(19) United States
(12) Patent Application Publication
(10) Pub. No.: US 2026/0149228 A1
(43) Pub. Date: May 28, 2026

(54) VEHICLE CHARGING SYSTEM FOR AN ELECTRIC VEHICLE HAVING ARC DETECTION

(71) Applicant: TE Connectivity Solutions GmbH, Schaffhausen (CH)

(72) Inventors: David Bruce Sarraf, Middletown, PA (US); Paul T. Angell, Middletown, PA (US); Nathan Philip Myer, Middletown, PA (US)

(21) Appl. No.: 19/064,909

(22) Filed: Feb. 27, 2025

Related U.S. Application Data
(60) Provisional application No. 63/724,578, filed on Nov. 25, 2024.

(51) Int. Cl. H01R 13/66; B60L 3/00; B60L 53/16; B60L 53/60; G01R 31/12

(52) U.S. Cl. CPC H01R 13/6683; B60L 3/0046; B60L 53/16; B60L 53/60; G01R 31/1209; G01R 31/1218; H01R 2201/26

(57) ABSTRACT

A vehicle charging system for an electric vehicle includes a housing having a DC charging terminal held by the housing in an internal cavity with a mating end for mating with the charging component and connected to a power cable. The vehicle charging system includes a charging controller for controlling vehicle charging along the DC charging terminal. The vehicle charging system includes an arc sensor in the internal cavity configured to detect an arc event at the mating end of the DC charging terminal. The arc sensor includes a light detector having a multi-modal diversity detector configured in a first mode to detect light from the arc event and configured in a second mode to detect an arc noise signature from the arc event. The arc sensor is operably coupled to the charging controller to control the vehicle charging when the arc event is detected.

### CROSS REFERENCE TO RELATED APPLICATIONS

This application claims benefit to U.S. Application No. 63/724,578, filed 25 Nov. 2024, titled “VEHICLE CHARGING SYSTEM FOR AN ELECTRIC VEHICLE HAVING ARC DETECTION” the subject matter of which is herein incorporated by reference in its entirety.

### BACKGROUND OF THE INVENTION

The subject matter herein relates generally to vehicle charging systems.

Electric vehicles (EV) and hybrid electric vehicles (HEV) include battery systems for operating the vehicles. The battery systems are charged by a vehicle charging system. For example, a charging connector, which is coupled to a power source, is connected to a charging inlet assembly of the vehicle to charge the battery. Known vehicle charging systems are not without disadvantages. For instance, the temperature of the terminals increase during charging, which may lead to damage to the charging components. In some instances, arcing may occur between the charging components, which can damage the charging connector and the charging inlet assembly.

A need remains for an arc detection method for a vehicle charging system of an electric vehicle.

### BRIEF DESCRIPTION OF THE INVENTION

In one embodiment, a vehicle charging system for an electric vehicle is provided and includes a housing having a mating end for mating with a charging component for the electric vehicle. The housing includes an internal cavity. The vehicle charging system includes a DC charging terminal held by the housing in the internal cavity. The DC charging terminal includes a mating end for mating with the charging component. The DC charging terminal is connected to a power cable. The vehicle charging system includes a charging controller for controlling vehicle charging along the DC charging terminal. The vehicle charging system includes an arc sensor in the internal cavity configured to detect an arc event at the mating end of the DC charging terminal. The arc sensor includes a light detector. The light detector is a multi-modal diversity detector configured in a first mode to detect light from the arc event and configured in a second mode to detect an arc noise signature from the arc event. The arc sensor is operably coupled to the charging controller to control the vehicle charging when the arc event is detected.

In another embodiment, a vehicle charging system for an electric vehicle is provided and includes a housing having a mating end for mating with a charging component for the electric vehicle. The housing includes an internal cavity. The vehicle charging system includes a DC charging terminal held by the housing in the internal cavity. The DC charging terminal includes a mating end for mating with the charging component. The DC charging terminal is connected to a power cable. The vehicle charging system includes a charging controller for controlling vehicle charging along the DC charging terminal. The vehicle charging system includes an arc sensor in the internal cavity configured to detect an arc event at the mating end of the DC charging terminal. The arc sensor includes a light detector. The light detector is a multi-modal diversity detector configured to detect light from the arc event in the optical frequency spectrum in a first mode and configured to detect electromagnetic waves from the arc event in the radio frequency spectrum in a second mode. The arc sensor is operably coupled to the charging controller to control the vehicle charging when the arc event is detected.

In a further embodiment, a charging inlet assembly for an electric vehicle is provided and includes a housing extending between a front and a rear. The housing has a chamber at the rear. The housing has a power connector at the front for receiving a charging connector. The power connector includes terminal channels between the front and the rear. The charging inlet assembly includes DC charging terminals coupled to the housing. Each of the DC charging terminals include a mating pin and a terminating end opposite the mating pin. The mating pin is positioned in the corresponding terminal channel for mating with the charging connector. The terminating end is positioned in the chamber at the rear of the housing. The charging inlet assembly includes a charging controller received in the chamber. The charging controller controls vehicle charging along the DC charging terminals. The charging inlet assembly includes an arc sensor in the internal cavity configured to detect an arc event at the mating pin of the DC charging terminal. The arc sensor includes a light detector. The light detector is a multi-modal diversity detector configured in a first mode to detect light from the arc event and configured in a second mode to detect an arc noise signature from the arc event. The arc sensor is operably coupled to the charging controller to control the vehicle charging when the arc event is detected.

### BRIEF DESCRIPTION OF THE DRAWINGS

FIG. 1 is a schematic view of a vehicle charging system in accordance with an exemplary embodiment.

FIG. 2 is a front perspective view of a charging component in accordance with an exemplary embodiment.

FIG. 3 is a rear perspective view of the charging component in accordance with an exemplary embodiment.

FIG. 4 is a perspective view of the charging controller in accordance with an exemplary embodiment.

FIG. 5 is a cross-sectional view of the charging component in accordance with an exemplary embodiment showing a second charging component coupled to the charging component.

FIG. 6 is a cross-sectional view of the charging component in accordance with an exemplary embodiment showing the second charging component coupled to the charging component.

### DETAILED DESCRIPTION OF THE INVENTION

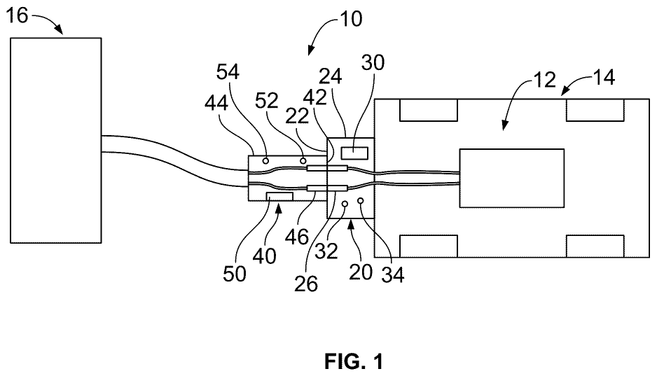

FIG. 1 is a schematic view of a vehicle charging system 10 in accordance with an exemplary embodiment. The vehicle charging system 10 is used for charging a battery system 12 of a vehicle 14, such as an electric vehicle or a hybrid electric vehicle. The vehicle charging system 10 includes a first charging component 20 and a second charging component 40. The first and second charging components 20, 40 are coupled together to charge the battery system 12 of the vehicle 14. In an exemplary embodiment, the first charging component 20 is coupled to the vehicle 14 and the second charging component 40 is coupled to a power supply 16 used for charging the battery system 12 of the vehicle 14. For example, the first charging component 20 may be a charging inlet assembly 22 mounted to the vehicle 14 and the second charging component 40 may be a charging connector 42 which may be provided at a charging station or coupled to the building wiring of the home or building where the vehicle 14 is parked.

The first charging component 20 includes a housing 24 holding a plurality of charging terminals 26. The charging terminals 26 may be DC charging terminals and/or AC charging terminals.

The first charging component 20 includes a charging controller 30, which may be used to control vehicle charging. For example, the charging controller 30 may control power supply along the charging terminals 26. The charging controller 30 may communicate with the second charging component 40, such as to control the second charging component 40. For example, the charging controller 30 may cause the second charging component 40 to turn on the power supply, turn off the power supply, increase power supply, and/or decrease power supply.

In an exemplary embodiment, the first charging component 20 includes a temperature sensor 32 operably coupled to the charging controller 30 to monitor a temperature of the charging terminals 26. The vehicle charging may be controlled based on the temperature readings of the temperature sensor 32. The temperature sensor 32 may be used for arc detection, such as by monitoring for a spike in temperature or a temperature above a threshold temperature, which may be higher than a normal operating temperature range.

In an exemplary embodiment, the first charging component 20 includes an arc sensor 34 operably coupled to the charging controller 30 to detect an arc event within the first charging component 20, such as at the charging terminal 26. The arc sensor 34 is operably coupled to the charging controller 30 to control the vehicle charging when the arc event is detected. For example, when the arc event is detected, the charging controller immediately shuts off the power supply to stop the charging process and extinguish the arc. In an exemplary embodiment, the arc sensor 34 may include a light detector, such as a photodiode, to detect light from the arc event. In an exemplary embodiment, the arc sensor 34 may be a diversity detector configured to detect the arc event using multiple detection methods, such as by operating in different modes or detecting different frequency ranges. For example, the arc sensor 34 may be a multi-modal diversity detector configured in a first mode to detect light from the arc event and configured in a second mode to detect an arc noise signature from the arc event. The arc sensor 34 may detect light in the optical frequency spectrum in the first mode and may detect electromagnetic waves in the radio frequency spectrum in the second mode. For example, the arc sensor 34 may detect optical waves in the first mode and may detect electrical waves and the second mode. The arc sensor 34 may be operable in the first mode and the second mode simultaneously. The arc sensor 34 may be configured to detect the arc event in the first mode with direct line of sight to the arc event and may be configured to detect the arc event in the second mode without direct line of sight to the arc event.

The second charging component 40 includes a housing 44 holding a plurality of charging terminals 46. The charging terminals 46 are configured to be mated with the charging terminals 26. In various embodiments, the charging terminals 46 are socket terminals and the charging terminals 26 are pin terminals; however, other types of terminals may be used in alternative embodiments. The charging terminals 46 may be DC charging terminals and or AC charging terminals.

The second charging component 40 includes a charging controller 50, which may be used to control vehicle charging. For example, the charging controller 50 may control power supply along the charging terminals 46. The charging controller 50 may communicate with the first charging component 20. The charging controller 50 may turn on the power supply, turn off the power supply, increase the power supply, and/or decrease the power supply. The charging controller 50 may control the voltage and/or current supplied by the second charging component 40.

In an exemplary embodiment, the second charging component 40 includes a temperature sensor 52 operably coupled to the charging controller 50 to monitor a temperature of the charging terminals 46. The vehicle charging may be controlled based on the temperature readings of the temperature sensor 52. The temperature sensor 52 may be used for arc detection, such as by monitoring for a spike in temperature or a temperature above a threshold temperature, which may be higher than a normal operating temperature range.

In an exemplary embodiment, the second charging component 40 includes an arc sensor 54 operably coupled to the charging controller 50 to detect an arc event at the mating interface, such as at the charging terminal 46. The arc sensor 54 is operably coupled to the charging controller 50 to control the vehicle charging when the arc event is detected. For example, when the arc event is detected, the charging controller immediately shuts off the power supply to stop the charging process and extinguish the arc. In an exemplary embodiment, the arc sensor 54 may include a light detector, such as a photodiode, to detect light from the arc event. In an exemplary embodiment, the arc sensor 54 may be a diversity detector configured to detect the arc event using multiple detection methods, such as by operating in different modes or detecting different frequency ranges. For example, the arc sensor 54 may be a multi-modal diversity detector configured in a first mode to detect light from the arc event and configured in a second mode to detect an arc noise signature from the arc event. The arc sensor 54 may detect light in the optical frequency spectrum in the first mode and may detect electromagnetic waves in the radio frequency spectrum in the second mode. For example, the arc sensor 54 may detect optical waves in the first mode and may detect electrical waves and the second mode. The arc sensor 54 may be operable in the first mode and the second mode simultaneously. The arc sensor 54 may be configured to detect the arc event in the first mode with direct line of sight to the arc event and may be configured to detect the arc event in the second mode without direct line of sight to the arc event.

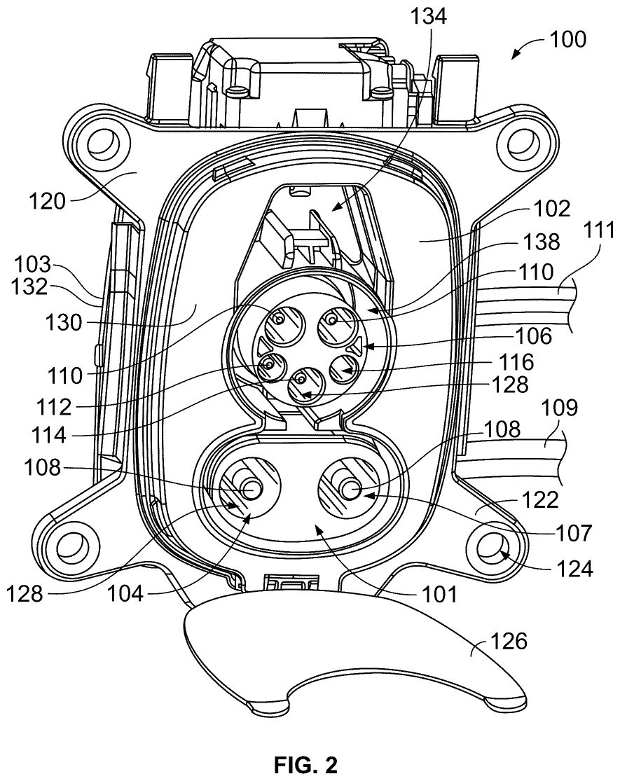

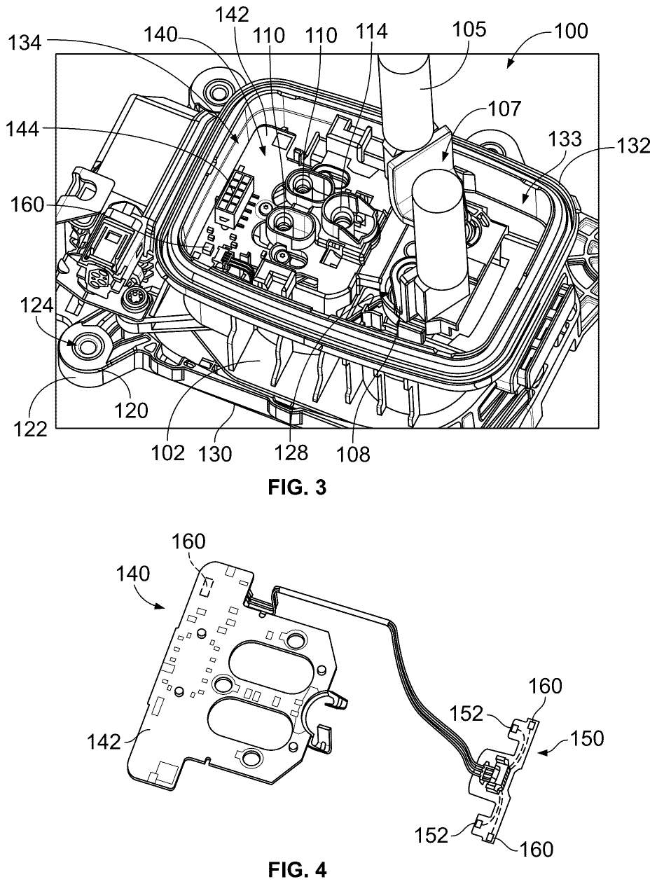

FIG. 2 is a front perspective view of a charging component 100 in accordance with an exemplary embodiment. FIG. 3 is a rear perspective view of the charging component 100 in accordance with an exemplary embodiment. In the illustrated embodiment, the charging component 100 is a charging inlet assembly and may be referred to hereinafter as a charging inlet assembly 100. The charging inlet assembly 100 is configured to be mated with a complimentary charging component (not shown), such as a charging connector or plug charger.

The charging inlet assembly 100 defines a power connector 101 configured to be electrically connected to the charging connector for charging a battery system of a vehicle, such as an electric vehicle (EV) or hybrid electric vehicle (HEV). In an exemplary embodiment, the charging inlet assembly 100 is configured for mating with a DC fast charging connector, such as the SAE combo CCS charging connector or the NACS charging connector, in addition to AC charging connectors, such as the SAE J1772 charging connector. In various embodiments, the charging inlet assembly 100 has a CCS1 (5 pin) AC configuration. In other various embodiments, the charging inlet assembly 100 may have a CCS2 (7 pin) AC configuration. Other standard inlet configurations may be used in alternative embodiments.

The charging inlet assembly 100 includes a housing 102 configured to be mounted in the vehicle. The housing 102 forms a portion of the power connector 101 for mating with the charging connector. A rear cover 103 (shown in FIG. 2 but removed in FIG. 3 to illustrate components of the charging inlet assembly 100) is coupled to a rear of the housing 102 to close out the housing 102 and the internal components of the charging inlet assembly 100. The rear cover 103 may be sealed to the housing 102 to prevent moisture and debris from entering the internal compartment of the housing 102. In an exemplary embodiment, the power connector 101 defines a DC charging portion 104 and an AC charging portion 106. The charging portions 104, 106 may form receptacles or openings that receive a plug of the charging connector. The charging inlet assembly 100 includes a plurality of charging terminals 107 for connection to the charging connector. Power cables 105 are electrically connected to the charging terminals 107 and routed within the vehicle, such as to the battery.

The DC charging portion 104 is configured for mating with an DC charging connector or an DC section of the charging connector. The DC charging portion may be used for fast charging. In an exemplary embodiment, the charging terminals 107 of the charging inlet assembly 100 includes DC charging terminals 108 at the DC charging portion 104, such as a pair of the DC charging terminals 108. The DC charging terminals 108 are configured to be electrically connected to the DC charging connector. The charging inlet assembly 100 includes DC power cables 109 (FIG. 2) electrically connected to the DC charging terminals 108. The DC power cables 109 may be terminated directly to the DC charging terminals 108, such as being crimped or welded to the DC charging terminals 108. In other embodiments, the DC power cables 109 may be electrically connected to the DC charging terminals 108 through a separable interface, such as through connectors mated to the housing 102 at the rear.

The AC charging portion 106 is configured for mating with an AC charging connector or an AC section of the charging connector. In an exemplary embodiment, the charging terminals 107 of the charging inlet assembly 100 includes AC power terminals 110 at the AC charging portion 106, such as a pair of the AC power terminals 110. The charging terminals 107 of the charging inlet assembly 100 include a proximity terminal 112 at the AC charging portion 106. The charging terminals 107 of the charging inlet assembly 100 include a ground terminal 114 at the AC charging portion 106. The charging terminals 107 of the charging inlet assembly 100 include a communication terminal 116 at the AC charging portion 106. The AC power terminals 110, the proximity terminal 112, the ground terminal 114, and the communication terminal 116 are configured to be electrically connected to the AC charging connector.

The charging inlet assembly 100 includes AC cables 111 (FIG. 2) electrically connected to the corresponding AC terminals 110, 112, 114, 116. The AC cables 111 may be terminated directly to the AC terminals 110, 112, 114, 116, such as being crimped or welded thereto. In other embodiments, the AC cables 111 may be electrically connected to the AC terminals 110, 112, 114, 116 through a separable interface, such as through connectors mated to the housing 102 at the rear.

The cables 109, 111 extend from the charging inlet assembly 100 to another component of the vehicle, such as the battery system of the vehicle. The cables 109, 111 transmit power, such as to the battery of the vehicle. The DC power cables 109 may transmit high voltage for charging the battery and the AC cables 111 may transmit low voltage for charging the battery. Optionally, one or more of the cables 111 may be electrically connected to a battery control unit (not shown) of the battery system, such as to transmit data between the charging inlet assembly 100 and the battery system, such as data relating to the charging operation. For example, the cable 111 may transmit data relating to charging start/stop, operating temperature of the power terminals 108 and/or 110, or other charging data. The cable 111 may send a proximity signal to the battery system indicating when the charging device is mated to the power connector 101 of the charging inlet assembly 100.

The charging inlet assembly 100 includes a mounting flange 120 (FIG. 1) coupled to the housing 102. The mounting flange 120 is used to couple the charging inlet assembly 100 to the vehicle. The mounting flange 120 includes mounting tabs 122 having openings 124 that receive fasteners (not shown) used to secure the charging inlet assembly 100 to the vehicle. Other types of mounting features may be used to secure the charging inlet assembly 100 to the vehicle. The mounting flange 120 may include a seal to seal the charging inlet assembly 100 to the vehicle.

In an exemplary embodiment, the charging inlet assembly 100 includes a terminal cover 126 (FIG. 2) at a front 130 of the housing 102. The terminal cover 126 is hingedly coupled to the mounting flange 120 and/or the housing 102. The terminal cover 126 is used to cover portions of the housing 102, such as the power connector 101. The terminal cover 126 may be used to cover the DC charging terminals 108 and/or the AC power terminals 110, which are located in corresponding terminal channels 128 in the housing 102.

The rear cover 103 is provided at a rear 132 of the housing 102 to close access to a rear chamber 133 at the rear 132 of the housing 102. The rear cover 103 may be clipped or latched onto the main part of the housing 102, such as using clips or latches. Other types of securing features, such as fasteners may be used in alternative embodiments. A perimeter seal may be provided between the rear cover 103 and the housing 102.

In an exemplary embodiment, the housing 102 of the charging inlet assembly 100 includes an internal cavity 134 that receives the components of the charging inlet assembly 100. The rear chamber 133 is at the rear of the internal cavity 134. The internal cavity 134 includes the terminal channels 128 that receive the corresponding charging terminals 107. The terminal channels 128 may be separated from each other and other components by walls of the housing 102. The internal cavity 134 includes a front chamber 138 at the front that receives the charging connector.

In an exemplary embodiment, the charging inlet assembly 100 includes a charging controller 140 for controlling charging of the vehicle through the charging inlet assembly 100. The charging controller 140 may be received in the internal cavity 134, such as in the rear chamber 133. The charging controller 140 may be communicatively coupled to the other charging component, such as the charging connector or plug, to control the charging activity. For example, the charging controller 140 may be communicatively coupled to the charging connector through one or more of the terminals 107. The charging controller 140 may turn on the power supply, turn off the power supply, increase the power supply, and/or decrease the power supply. The charging controller 140 may be located remote from the housing 102, such as at the battery control module of the vehicle charging system.

With additional reference to FIG. 4, which is a perspective view of the charging controller 140 in accordance with an exemplary embodiment, the charging controller 140 includes a circuit board 142, a control device 144, and other various components and circuitry to control operation of the charging inlet assembly 100. The control device 144 may be a processor or microcontroller. The control device 144 may include a multi-pin connector coupled to the circuit board 142.

In an exemplary embodiment, the control assembly includes one or more sensors 150 used to control the charging operation. The sensors 150 are used to sense operating characteristics of the components or the charging process to control charging. The sensors 150 are connected to the charging controller 140, such as being connected to the circuit board 142 by a wire or connector.

In various embodiments, the sensors 150 include temperature sensors 152. The temperature sensors 152 monitor operating temperatures of the DC charging terminals 108. The charging operation may be controlled based on the operating temperatures of the DC charging terminals 108. For example, as the temperature increases or approaches an allowable operating temperature, the power supply may be decreased. For example, the voltage or current may be reduced. The charging operation may stop if the operating temperature of the DC charging terminals 108 is above a threshold temperature. The temperature sensor 152 may be used for arc detection, such as by monitoring for a spike in temperature or a temperature above a threshold temperature, which may be higher than a normal operating temperature range.

In various embodiments, the sensors 150 include arc sensors 160. The arc sensors 160 detect an arc event within the charging inlet assembly 100, such as at mating ends of the DC charging terminals 108. The charging operation may be controlled based on the detection of the arc event. For example, when the arc event is detected, the charging operation is stopped. The current and voltage from the charging connector is stopped immediately to prevent damage to the components or the vehicle.

In an exemplary embodiment, the arc sensor 160 may include a light detector, such as a photodiode, to detect light from the arc event. In an exemplary embodiment, the arc sensor 160 may be a diversity detector configured to detect the arc event using multiple detection methods, such as by operating in different modes or detecting different frequency ranges. For example, the arc sensor 160 may be a multi-modal diversity detector configured in a first mode to detect light from the arc event and configured in a second mode to detect an arc noise signature from the arc event. The arc sensor 160 may detect light in the optical frequency spectrum in the first mode and may detect electromagnetic waves in the radio frequency spectrum in the second mode. For example, the arc sensor 160 may detects optical waves in the first mode and may detect electrical waves and the second mode. The arc sensor 160 may be operable in the first mode and the second mode simultaneously. The arc sensor 160 may be configured to detect the arc event in the first mode with direct line of sight to the arc event and may be configured to detect the arc event in the second mode without direct line of sight to the arc event.

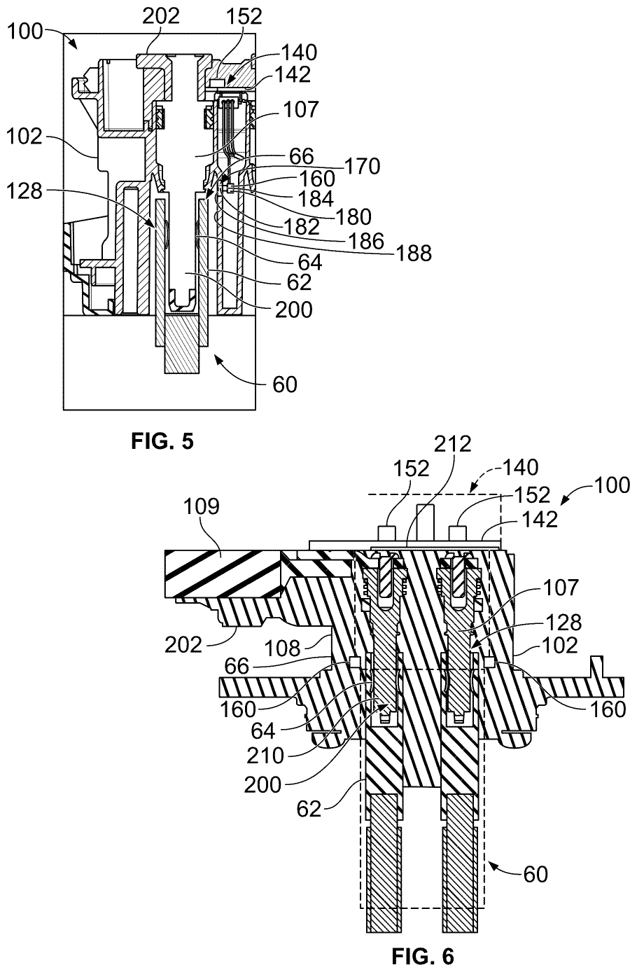

FIG. 5 is a cross-sectional view of the charging component 100 in accordance with an exemplary embodiment showing a second charging component 60 coupled to the charging component. FIG. 6 is a cross sectional view of the charging component 100 in accordance with an exemplary embodiment showing the second charging component 60 coupled to the charging component. In the illustrated embodiment, the charging component 100 is the charging inlet assembly. The second charging component 60 is a charging connector such as a plug charger.

The charging terminals 107 are shown in the terminal channels 128 of the housing 102. The charging terminals 107 are mated with charging terminals 62 of the charging connector 60. In the illustrated embodiment, the charging terminals 107 are pin terminals and the charging terminals 62 are socket terminals having spring contacts 64 in the sockets configured to electrically connect the charging terminals 62 and the charging terminals 107. The spring contacts 64 form a compliant, separable interface. The spring contacts 64 may be susceptible to failure due to overheating, and the failure may lead to an electrical arc event. The temperature sensors 152 monitor temperature of the charging terminals 107. The arc sensors 160 monitor the mating zone for arc events, such as at mating ends 66 of the charging terminals 62 or mating ends of the charging terminals 107.

The charging terminal 107 includes a mating pin 200 at a mating end 210 of the charging terminal 107 and a cable connector 202 at a rear 212 of the charging terminal 107. The charging terminal 107 extends along a longitudinal axis. The mating pin 200 is configured to be mated to the spring contact 64 of the charging terminal 62 of the charging connector 60. The cable connector 202 is configured to be electrically connected to the power cable 109. In various embodiments, the cable connector 202 is configured to be terminated to the power cable 109 by crimping to the power cable 109. In other various embodiments, the cable connector 202 is terminated to the power cable 109 by other processes, such as being welded to a weld tab at the rear end of the charging terminal 107. The cable 109 may extend from the charging terminal 107 perpendicular to the longitudinal axis. Alternatively, the cable 109 may extend from the charging terminal 107 parallel to the longitudinal axis.

In an exemplary embodiment, the temperature sensor 152 is coupled to the charging terminal 107 at the rear of the charging terminal 107, such as at the cable connector 202. The charging terminal 107 is both electrically conductive and thermally conductive. As the mating pin 200 heats up during charging, the entire body of the charging terminal 107 similarly heats up. Such increase in temperature is detected by the temperature sensor 152. In various embodiments, the temperature sensor 152 is a thermistor. The temperature sensor 152 may include a resistance temperature detector.

The arc sensor 160 detects an arc event within the charging inlet assembly 100, such as at the mating ends 210. In various embodiments, the arc sensor 160 monitors for light generated by the arc event to detect the arc event. In various embodiments, the arc sensor 160 monitors for an arc noise signature to detect the arc event. In an exemplary embodiment, the arc sensor 160 is a multi-modal diversity detector configured to detect the arc event using multiple detection methods by operating in different modes. For example, in a first mode, the arc sensor 160 detects light from the arc event and in a second mode the arc sensor 160 detects an arc noise signature from the arc event.

In an exemplary embodiment, the arc sensor 160 includes a light detector 180, such as a photodiode, to detect light from the arc event (in the first mode). For example, light is generated by the arc event, such as in the optical frequency range. The light of the electrical arcing may be in a predetermined range, such as infrared frequency range and/or visible frequency range and/or ultraviolet frequency range. The light detector 180 is positioned to visibly monitor the internal cavity 134, such as in the terminal channel 128, to detect the arc event in the vicinity of the mating interface between the charging terminals 107, 62. The light detector 180 may be position in the internal cavity 134, such as in the terminal channel 128. In other various embodiments, the light detector 180 is located in the housing 102, such as at a window 170 to the internal cavity 134, to monitor the mating interface for an arc event through the window 170. The window 170 is transparent, such as being a transparent plastic, to allow detection of the arc event through the window 170. The light detector 180 is insulated from the charging terminals 107, 62 by the window 170. For example, the window 170 may be a dielectric material. The light detector 180 detects light in the optical frequency spectrum. For example, the light detector 180 may detect optical waves. The light detector 180 is configured to detect the arc event with direct line of sight to the arc event.

In an exemplary embodiment, a light guide 182 extends between the terminal channel 128 and the light detector 180. The light guide 182 may be an optical fiber. The light guide 182 extends between a first end 184 and a second end 186. The first end 184 is coupled to the light detector 180. The second end 186 is positioned proximate to the mating end of the charging terminal 107. Light from the arc event is transmitted from the second end 186 to the first end 184 for detection by the light detector 180. In an exemplary embodiment, a UV sensitive coating 188 may be applied on the housing 102 proximate to the mating end of the charging terminal 107, such as within the terminal channel 128. The UV sensitive coating 188 is activated during the arc event to increase the light produced during the arc event for quicker and or more reliable monitoring by the light detector 180.

Arcing at the mating interface happens in air. When brought to an excited state by an arc the nitrogen and oxygen in the air emit light. The two strongest emission lines for oxygen are at 430 nm and 538 nm, which are near-UV and deep blue, respectively. Since light is not normally present inside the mated connector, light output detected by the light detector 180 would indicate onset of arcing. The light detector 180 may detect light that leaks through small gaps in the mated connector or light that has been routed from the terminal region to the sensor by the light guide 182. The light guide 182 may be routed through the housing 102 without compromising the electrical insulative properties of the housing 102. Detection of leaked light could be enhanced by coating the interior connector walls with a UV-sensitive phosphor that more effectively spreads light to the light detector 180.

In an exemplary embodiment, the arc sensor 160 monitors for an arc noise signature to detect the arc event. For example, arc noise is generated by the arc event, such as in the radiofrequency range as a consequence of arc energy. The characteristic noise signature of the electrical arcing may be in a predetermined range, such as between 1 kHz-100 GHz. The characteristic noise signature of the electrical arcing may be in a more particular range, such as between 100-500 kHz. The arc sensor 160 detects the stochastic energy, or noise signature, generated by the electrical arc. In an exemplary embodiment, the arc sensor 160 may monitor an electrical circuit of the charging inlet assembly 100 to detect the arc noise signature on the electrical circuit corresponding to the arc event. The electrical circuit may be the power circuit, such as along the charging terminals 107 and/or the power cables 109. The electrical circuit may be a circuit of the charging controller 140, such as a circuit on the circuit board 142 (FIG. 3). The arc sensor 160 may monitor a spectrogram of a signal on the electrical circuit to detect the arc noise signature. The arc sensor 160 may monitor for a rise in amplitude on the electrical circuit indicative of arcing. The arc sensor 160 is configured to detect the arc event (in the second mode) without direct line of sight to the arc event, such as by detecting the noise signature energy generated by the electrical arc.

Electrical conduction in an arc is a stochastic process that generates a characteristic noise signature, such as between 100-500 kHz. In contrast, the light detector 180 of the arc sensor 160 may generate a spike detection signal during the arc event associated with the light detection by the light detector 180. The arc noise signature can be readily distinguished by the arc sensor 160 from the light detection signal. In various embodiments, the arc noise signature may be detected by identifying a rise in amplitude over the arc noise frequency range (for example, 100-500 kHz range), which would indicate the onset of arcing. The arc noise signature may improve detection of arcing, such as by eliminating false positive events, such as from a raised detection signal on no arcing event and/or by eliminating false negative events, such as from missed arcing events from low light detection during an arcing event.

In various embodiments, the charging controller 140 may include an arc fault circuit interrupter (AFCI) device to protect against electrical arcing, such as to shut down the charging circuit when an arc is detected. The arc sensor 160 monitors for the arc noise signature on the electrical circuit to detect the arc noise signature conducted on the electrical circuit when the arc fault occurs. The charging controller 140 may include an internal processor in the ACFI device that distinguishes between normal operation and the hazardous arcing and will automatically open the circuit to reduce the risk of damage to the system.

In various embodiments, the arc sensor 160 is connected to other wiring or circuits to detect the arc noise signature. In other various embodiments, the arc sensor 160 includes a separate, dedicated arc detection wire, which may be routed from the charging terminal 107 to the circuit board 142 or routed to another component, such as the battery control module. The arc sensor 160 may include a resistor-capacitor-inductor network at the charging terminal 107 or at the circuit board 142 to enhance sensitivity to arc signature and minimize sensitivity to normal vehicle electrical noise.

In an exemplary embodiment, the arc sensor 160 noise is electrically coupled to the electrical circuit at or near the cable connector 202 at the rear 212 of the charging terminal 107. The arc sensor 160 may be coupled to the cable connector 202 or to the cable 109. In various embodiments, the arc sensor 160 may include a current transformer around the power cable 109 to monitor the electrical signature along the cable 109. In other various embodiments, the arc sensor 160 may include a Hall sensor adjacent to the cable 109 or the cable connector 202 to monitor the electrical signature along the electrical circuit. In various embodiments, the arc sensor 160 includes an induction coil to monitor the electrical signature along the electrical circuit. The induction coil may be positioned at or near the cable connector 202 or the cable 109. The induction coil may be provided on a circuit board, such as the circuit board 142 or another circuit board, such as a circuit board for the temperature sensor system. In various embodiments, the induction coil is broadly tuned with a capacitor. The arc sensor 160 may include isolation from the power circuit, such as from the conductors of the cable 109 or the cable connector 202 to prevent damage to the arc sensor 160. For example, the current transformers, the hall sensor and/or the induction coil may have electrical isolation from the conductors carrying charging current. Electrical isolation may be provided by suitable DC blocking capacitors to isolate the components from the charging current conductors.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A vehicle charging system for an electric vehicle comprising:
a housing having a mating end for mating with a charging component for the electric vehicle, the housing including an internal cavity;
an DC charging terminal held by the housing in the internal cavity, the DC charging terminal including a mating end for mating with the charging component, the DC charging terminal being connected to a power cable;
a charging controller for controlling vehicle charging along the DC charging terminal; and
an arc sensor in the internal cavity configured to detect an arc event at the mating end of the DC charging terminal, the arc sensor including a light detector, the light detector being a multi-modal diversity detector configured in a first mode to detect light from the arc event and configured in a second mode to detect an arc noise signature from the arc event, the arc sensor being operably coupled to the charging controller to control the vehicle charging when the arc event is detected.

2. The vehicle charging system of claim 1, wherein the light detector is a photodiode.

3. The vehicle charging system of claim 1, wherein the arc sensor detects light in the optical frequency spectrum in the first mode and detects electromagnetic waves in the radio frequency spectrum in the second mode.

4. The vehicle charging system of claim 1, wherein the arc sensor detects optical waves in the first mode and detects electrical waves and the second mode.

5. The vehicle charging system of claim 1, wherein the arc sensor is operable in the first mode and the second mode simultaneously.

6. The vehicle charging system of claim 1, wherein the arc sensor is configured to detect the arc event in the first mode with direct line of sight to the arc event, the arc sensor being configured to detect the arc event in the second mode without direct line of sight to the arc event.

7. The vehicle charging system of claim 1, wherein the arc sensor is located in the internal cavity of the housing.

8. The vehicle charging system of claim 1, wherein the housing includes a window to the internal cavity, the arc sensor be located in the housing at the window and being insulated from the DC charging terminal by the window.

9. The vehicle charging system of claim 1, wherein the charging controller shuts power supplied to the DC charging terminal when the arc event is detected.

10. The vehicle charging system of claim 1, wherein the housing is a charging connector housing configured to be removably coupled to a charging inlet housing of the charging component of the vehicle, the DC charging terminal being a socket terminal configured to be mated with a pin terminal of the charging component to power the vehicle through the pin terminal.

11. The vehicle charging system of claim 1, wherein the housing is a charging inlet housing configured to be mounted to the vehicle and configured to receive a charging connector housing of the charging component, the DC charging terminal including a pin configured to be mated with a socket terminal of the charging component to receive power from the charging component.

12. The vehicle charging system of claim 1, further comprising a temperature sensor monitoring temperature of the DC charging terminal, the temperature sensor being operably coupled to the charging controller to control the vehicle charging based on the temperature of the DC charging terminal.

13. The vehicle charging system of claim 1, further comprising a light guide extending between a first end and a second end, the first end being coupled to the light detector, the second end being positioned proximate to the mating end of the DC charging terminal.

14. The vehicle charging system of claim 1, further comprising a UV sensitive coating on the housing proximate to the mating end of the DC charging terminal activated during the arc event.

15. A vehicle charging system for an electric vehicle comprising:
a housing having a mating end for mating with a charging component for the electric vehicle, the housing including an internal cavity;
an DC charging terminal held by the housing in the internal cavity, the DC charging terminal including a mating end for mating with the charging component, the DC charging terminal being connected to a power cable;
a charging controller for controlling vehicle charging along the DC charging terminal; and
an arc sensor in the internal cavity configured to detect an arc event at the mating end of the DC charging terminal, the arc sensor including a light detector, the light detector being a multi-modal diversity detector configured to detect light from the arc event in the optical frequency spectrum in a first mode and configured to detect electromagnetic waves from the arc event in the radio frequency spectrum in a second mode, the arc sensor being operably coupled to the charging controller to control the vehicle charging when the arc event is detected.

16. The vehicle charging system of claim 15, wherein the light detector detects optical waves in the first mode and detects electrical waves and the second mode.

17. The vehicle charging system of claim 15, wherein the light detector is configured to detect the arc event in the first mode with direct line of sight to the arc event, the light detector being configured to detect the arc event in the second mode without direct line of sight to the arc event.

18. The vehicle charging system of claim 15, wherein the charging controller shuts power supplied to the DC charging terminal when the arc event is detected.

19. A charging inlet assembly for an electric vehicle comprising:
a housing extending between a front and a rear, the housing having a chamber at the rear, the housing having a power connector at the front for receiving a charging connector, the power connector including terminal channels between the front and the rear;
DC charging terminals coupled to the housing, each of the DC charging terminals including a mating pin and a terminating end opposite the mating pin, the mating pin positioned in the corresponding terminal channel for mating with the charging connector, the terminating end positioned in the chamber at the rear of the housing;
a charging controller received in the chamber, the charging controller controlling vehicle charging along the DC charging terminals; and
an arc sensor in the internal cavity configured to detect an arc event at the mating pin of the DC charging terminal, the arc sensor including a light detector, the light detector being a multi-modal diversity detector configured in a first mode to detect light from the arc event and configured in a second mode to detect an arc noise signature from the arc event, the arc sensor being operably coupled to the charging controller to control the vehicle charging when the arc event is detected.

20. The charging inlet assembly of claim 19, wherein the light detector detects light in the optical frequency spectrum in the first mode and detects electromagnetic waves in the radio frequency spectrum in the second mode.
